(19) United States
(12) Patent Application Publication
(10) Pub. No.: US 2011/0151765 A1
(43) Pub. Date: Jun. 23, 2011

(54) OPERATING CONDITION ADJUSTING SYSTEM AND METHOD OF PORTABLE DATA CENTER

(75) Inventors: Peng-Yuan Chen, Taoyuan Hsien (TW); Wei-Zhi Lin, Taoyuan Hsien (TW); Ming-Feng Kang, Taoyuan Hsien (TW)

(73) Assignee: DELTA ELECTRONICS, INC., Taoyuan Hsien (TW)

(21) Appl. No.: 12/967,504

(22) Filed: Dec. 14, 2010

(30) Foreign Application Priority Data
Dec. 17, 2009 (TW) 098143444

(51) Int. Cl. H05K 5/00

(52) U.S. Cl. 454/184

(57) ABSTRACT

An operating condition adjusting system includes a shipping container, plural computer cabinets, an airflow-guiding device, a controlling unit and a first sensor. The shipping container includes a first gate and a second gate. The plural computer cabinets are accommodated within the shipping container. A first airflow is introduced into the computer cabinets to remove a portion of heat of the computer cabinets, and a second airflow is exhausted from the computer cabinets. The airflow-guiding device is used for guiding the first airflow to flow toward the computer cabinets. The controlling unit is used for controlling the first gate and the second gate. The first sensor is electrically connected with the controlling unit for detecting a first temperature of an external environment. By comparing the first temperature with a second temperature, the first gate and the second gate are opened or closed under control of the controlling unit.

### FIELD OF THE INVENTION

The present invention relates to an operating condition adjusting system and an operating condition adjusting method of a portable data center, and more particularly to an operating condition adjusting system and an operating condition adjusting method of a portable data center in order to reduce energy consumption.

### BACKGROUND OF THE INVENTION

A data center is a facility to house computer systems and associated components such as servers, telecommunication device and storage devices. The data center is designed to provide a controlled environment for efficient operation of computer systems. During operations of the computer systems, a substantial amount of heat is generated. If the heat is not effectively dissipated, the performance of the computer systems will be deteriorated. It is critical to adjust the operating conditions of the data center.

The current portable data center is a closed portable data center. The computer cabinets are disposed within the closed shipping container of the portable data center. The current portable data center uses a heat exchanger to reduce the internal temperature of the shipping container. In other words, the airflow is circulated within the closed shipping container. After the airflow within the shipping container is heated by the computer cabinets, the heated airflow is cooled by the heat exchanger. In other words, the operating condition of the data center is adjusted by circulating the airflow. Since the heat exchanger is continuously turned on, the electricity of the heat exchanger is continuously consumed. In other words, the current portable data center fails to the meet the power-saving requirements.

Therefore, there is a need of providing an operating condition adjusting system and an operating condition adjusting method of a data center so as to obviate the drawbacks encountered from the prior art.

### SUMMARY OF THE INVENTION

It is an object of the present invention to provide an operating condition adjusting system and an operating condition adjusting method of a data center in order to reduce power consumption.

In accordance with an aspect of the present invention, there is provided an operating condition adjusting system of a data center. The operating condition adjusting system includes a shipping container, plural computer cabinets, an airflow-guiding device, a controlling unit and a first sensor. The shipping container includes at least one first gate and at least one second gate. The plural computer cabinets are accommodated within the shipping container. A first airflow is introduced into the computer cabinets to remove a portion of heat of the computer cabinets, and a second airflow is exhausted from the computer cabinets. The airflow-guiding device is disposed within the shipping container for guiding the first airflow to flow toward the computer cabinets. The controlling unit is used for controlling the first gate and the second gate of the shipping container. The first sensor is electrically connected with the controlling unit for detecting a first temperature of an external environment. By comparing the first temperature with a second temperature, the first gate and the second gate are opened or closed under control of the controlling unit.

In accordance with another aspect of the present invention, there is provided an operating condition adjusting method for use in an operating condition adjusting system of a data center. The operating condition adjusting system includes a shipping container, plural computer cabinets, an airflow-guiding device, a heat exchanger and a controlling unit. The shipping container includes a first gate and a second gate. The shipping container is in communication with an external environment when the first gate and the second gate are opened, the computer cabinets, the heat exchanger and the airflow-guiding device are accommodated with the shipping container. A first airflow is guided by the airflow-guiding device to the computer cabinets to remove a portion of heat of the computer cabinets. A second airflow is exhausted from the computer cabinets. The operating condition adjusting method is controlled by the controlling unit. The operating condition adjusting method includes steps of: (a) detecting a first temperature of the external environment, (b) comparing the first temperature with a second temperature and an allowable temperature of the shipping container, and (c) controlling on/off statuses of the first gate and the second gate and adjusting a heat-exchanging magnitude of the heat exchanger according to a result of comparing the first temperature with the second temperature and the allowable temperature.

The above contents of the present invention will become more readily apparent to those ordinarily skilled in the art after reviewing the following detailed description and accompanying drawings, in which:

### BRIEF DESCRIPTION OF THE DRAWINGS

FIG. 1A is a schematic left-side view illustrating an operating condition adjusting system of a data center according to an embodiment of the present invention;

FIG. 1B is a schematic right-side view illustrating the operating condition adjusting system of FIG. 1A;

FIG. 1C is a schematic cross-sectional view illustrating the operating condition adjusting system of FIG. 1A and taken along the line a-a′;

FIG. 2 is a schematic functional block diagram illustrating a controlling mechanism of the controlling unit of the operating condition adjusting system of FIG. 1C;

FIG. 3A is a flowchart illustrating an operating condition adjusting method according to an embodiment of the present invention;

FIG. 3B is a detailed flowchart illustrating Step S12 and S13 of the operating condition adjusting method as illustrated in FIG. 3A;

FIG. 3C is a schematic cross-sectional view illustrating an exemplary operating condition adjusting system of the present invention, in which the shipping container is in a close circulation status;

FIG. 3D is a schematic cross-sectional view illustrating an exemplary operating condition adjusting system of the present invention, in which the shipping container is in an open circulation status;

FIG. 3E is a detailed flowchart illustrating Step S12˜S16 of the operating condition adjusting method as illustrated in FIG. 3A;

FIG. 3F is a schematic cross-sectional view illustrating another exemplary operating condition adjusting system of the present invention, in which the shipping container is in an open circulation status;

FIG. 4 is a schematic cross-sectional view illustrating an operating condition adjusting system according to another embodiment of the present invention; and

FIG. 5 is a schematic functional block diagram illustrating a controlling mechanism of the controlling unit of the operating condition adjusting system of FIG. 4.

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

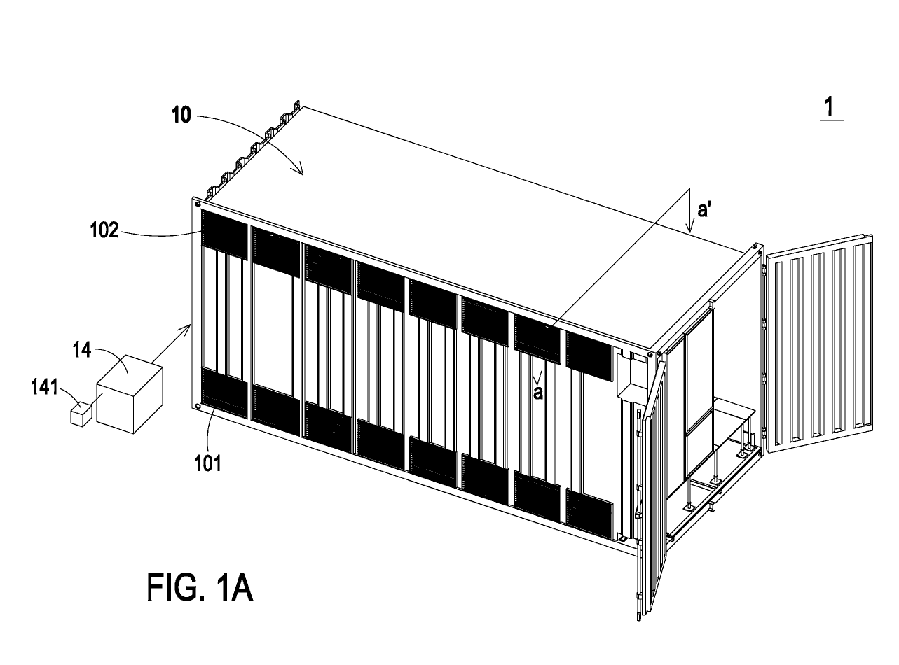

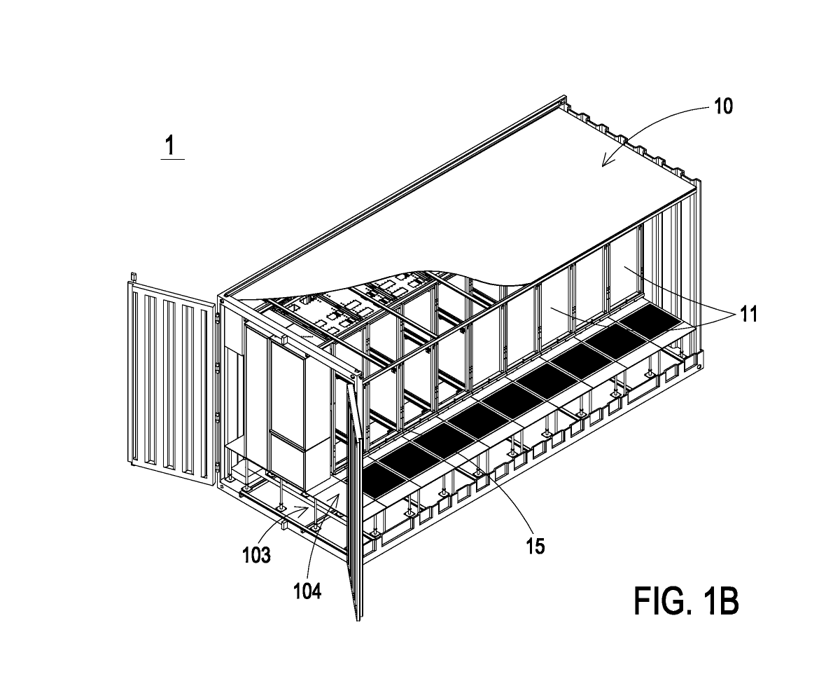

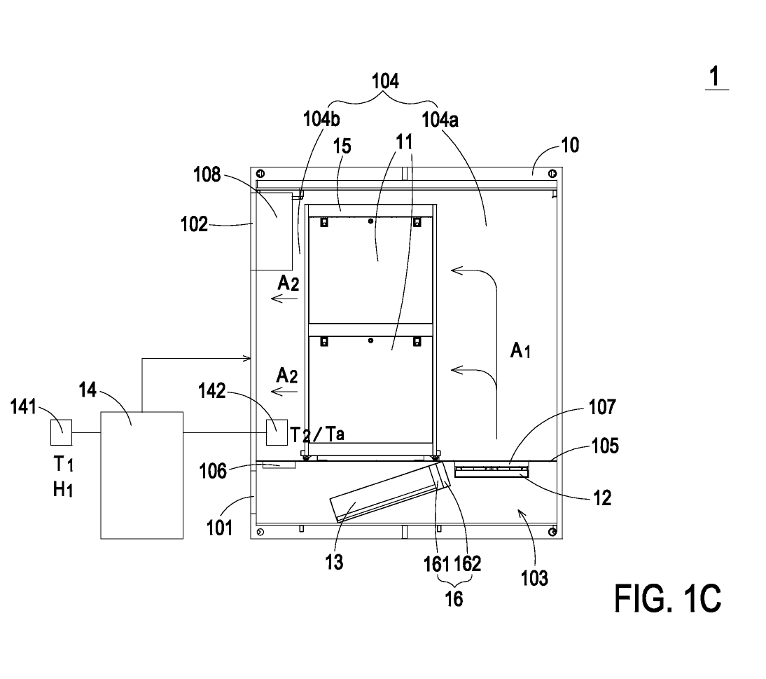

FIG. 1A is a schematic left-side view illustrating an operating condition adjusting system of a data center according to an embodiment of the present invention. FIG. 1B is a schematic right-side view illustrating the operating condition adjusting system of FIG. 1A. FIG. 1C is a schematic cross-sectional view illustrating the operating condition adjusting system of FIG. 1A and taken along the line a-a′. Please refer to FIGS. 1A, 1B and 1C. The operating condition adjusting system 1 of a data center comprises a shipping container 10, plural computer cabinets 11, an airflow-guiding device 12, a controlling unit 14 and a first sensor 141. The shipping container 10 comprises at least one first gate 101 and at least one second gate 102. The plural computer cabinets 11 are accommodated within the shipping container 10. A first airflow A1 is introduced into the computer cabinets 11 to remove a portion of heat of the computer cabinets 11, and thus a second airflow A2 is exhausted from the computer cabinets 11. The airflow-guiding device 12 is disposed within the shipping container 10 for guiding the first airflow A1 to flow toward the computer cabinets 11. The first sensor 141 is used to detect a first temperature T1 of the external environment. The controlling unit 14 is electrically connected to the first sensor 141 for controlling the first gate 101 and the second gate 102 of the shipping container 10. By comparing the first temperature T1 and a second temperature T2, the first gate 101 and the second gate 102 are opened or closed under control of the controlling unit 14. For clearly showing the internal structure of the shipping container 10, the door of the shipping container 10 is opened (see FIGS. 1A and 1B) and a portion of sidewall is omitted (see FIG. 1B). During operation of the data center, the door of the shipping container 10 is closed in order to control the operating conditions of the data center.

Please refer to FIG. 1C again. The shipping container 10 further comprises a first compartment 103 and a second compartment 104. The first compartment 103 and the second compartment 104 are separated from each other by a partitioning structure 105. In this embodiment, the portioning structure 105 is horizontally arranged within the shipping container 10. The second compartment 104 is disposed over the first compartment 103. The operating condition adjusting system 1 further comprises a heat exchanger 13. The heat exchanger 13 is disposed within the first compartment 103. The computer cabinets 11 contain computer components (e.g. servers and storage devices) are disposed within the second compartment 104. Optionally, a support frame 15 is disposed within the second compartment 104 for supporting the computer cabinets 11. The second compartment 104 includes an air-inlet zone 104a and an air-outlet zone 104b. The air-inlet zone 104a and the air-outlet zone 104b are substantially separated from each other by the computer cabinets 11. The first airflow A1 (e.g. a cold airflow) is introduced into the computer cabinets 11 through the air-inlet zone 104a to remove a portion of heat of the computer cabinets 11, and then a second airflow A2 (a heated airflow) is exhausted from the computer cabinets 11 to the air-outlet zone 104b. The first gate 101 is formed in a sidewall of the first compartment 103. The second gate 102 is formed in a sidewall of the second compartment 104. In this embodiment, the first gate 101 and the second gate 102 are movable ventilation doors, which are controllable by the controlling unit 14 to be opened or closed. In a case that the first gate 101 is opened, the first compartment 103 is in fluid communication with the external environment. In a case that the second gate 102 is opened, the air-outlet zone 104b of the second compartment 104 is in fluid communication with the external environment. Optionally, a fan 108 is disposed at the second gate 102. The fan 108 is also controllable by the controlling unit 14.

Please refer to FIG. 1C again. The shipping container 10 further comprises a third gate 106 and a fourth gate 107. Via the third gate 106 and the fourth gate 107, the first compartment 103 and the second compartment 104 are in communication with each other. In this embodiment, the third gate 106 and the fourth gate 107 are formed in the partitioning structure 105 and penetrated through the partitioning structure 105. The third gate 106 is arranged between the first compartment 103 and the air-outlet zone 104b of the second compartment 104. In this embodiment, the third gate 106 is a movable ventilation door, which is controllable by the controlling unit 14 to be opened or closed. In a case that the third gate 106 is opened, the air-outlet zone 104b of the second compartment 104 is in fluid communication with the first compartment 103. Whereas, in case that the third gate 106 is closed, the first compartment 103 and the air-outlet zone 104b are isolated from each other. The fourth gate 107 is arranged between the first compartment 103 and the air-inlet zone 104a of the second compartment 104. Via the fourth gate 107, the first compartment 103 is in fluid communication with the air-inlet zone 104a. In this embodiment, the airflow-guiding device 12 is arranged at the fourth gate 107, and controlled by the controlling unit 14. An example of the airflow-guiding device 12 is a variable-frequency fan. The location and type of the airflow-guiding device 12 are not restricted. Any device capable of guiding the first airflow A1 to flow toward the computer cabinets 11 can be used as the airflow-guiding device 12.

Please refer to FIG. 1C again. The operating condition adjusting system 1 further comprises a heat exchanger 13, which is controllable by the controlling unit 14. The heat exchanger 13 is disposed within the first compartment 103. An example of the heat exchanger 13 is a water-cooling coil. The heat exchanger 13 is in communication with a water chiller and a chilled water pump (not shown), which are disposed outside the shipping container 10. An example of the water chiller includes but is not limited to a variable-frequency water chiller. Moreover, the operating condition adjusting system 1 further comprises a humidity adjusting device 16, which is controllable by the controlling unit 14. The humidity adjusting device 16 is also disposed within the first compartment 103. The humidity adjusting device 16 comprises a dehumidifying unit 161 and a humidifying unit 162. An exemplary dehumidifying unit 161 is a heating coil. An exemplary humidifying unit 162 is a spray humidifier. Any other device having the dehumidifying and humidifying functions may be used as the humidity adjusting device 16 of the present invention. The heat exchanger 13 and the humidity adjusting device 16 are disposed within the first compartment 103, and arranged between the first gate 101 and the fourth gate 107, and between the third gate 106 and the fourth gate 107.

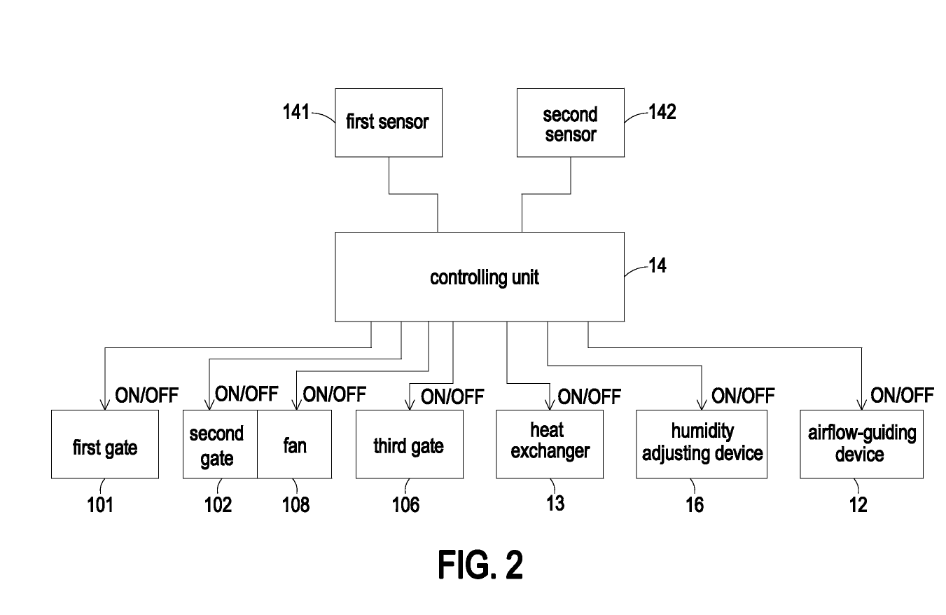

FIG. 2 is a schematic functional block diagram illustrating a controlling mechanism of the controlling unit of the operating condition adjusting system of FIG. 1C. Please refer to FIGS. 1C and 2. The controlling unit 14 is electrically connected with the first sensor 141. The first sensor 141 is disposed outside the shipping container 10. An example of the first sensor 141 is a temperature and humidity sensor for detecting the first temperature T1 and a first humidity H1 of the external environment. The controlling unit 14 is also electrically connected with a second sensor 142. The second sensor 142 is arranged in the path of the second airflow A2. That is, the second sensor 142 is also disposed in the air-outlet zone 104b of the second compartment 104. It is preferred that the second sensor 142 is in the vicinity of the third gate 106 in order to detect the temperature Ta of the second airflow A2. The second temperature T2 is a variable predetermined value, which is set to be equal to the temperature Ta of the second airflow A2. By comparing the first temperature T1 with the second temperature T2, the first gate 101, the second gate 102, the fan 108, the third gate 106, the heat exchanger 13, the humidity adjusting device 16 and the airflow-guiding device 12 are controlled by the controlling unit 14.

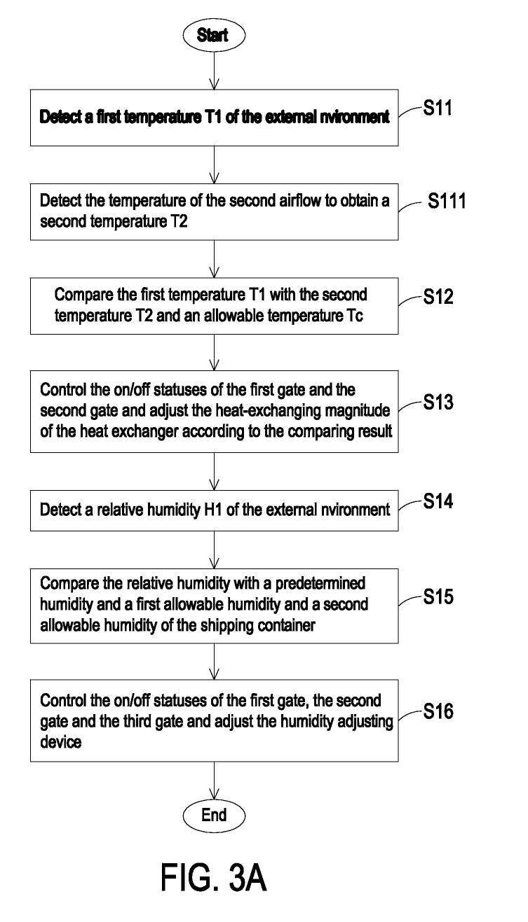

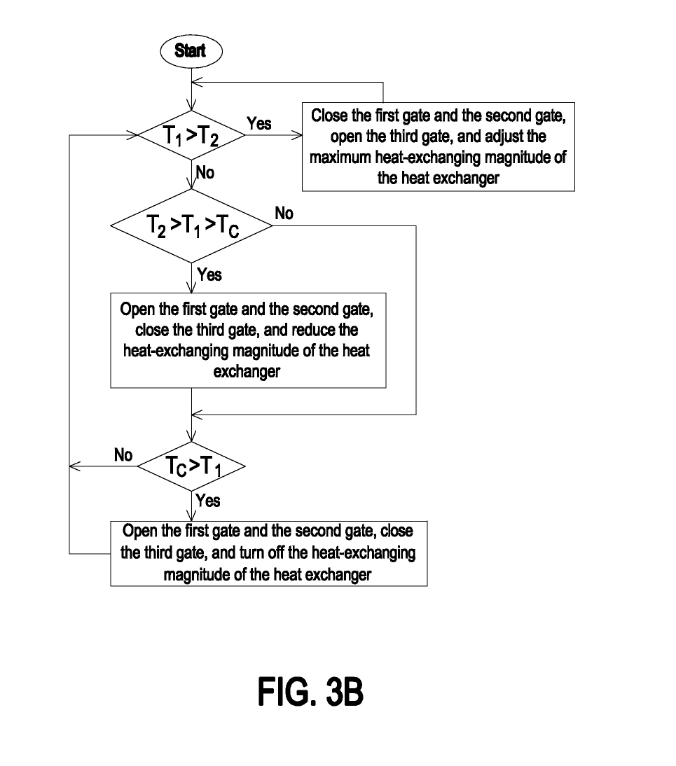

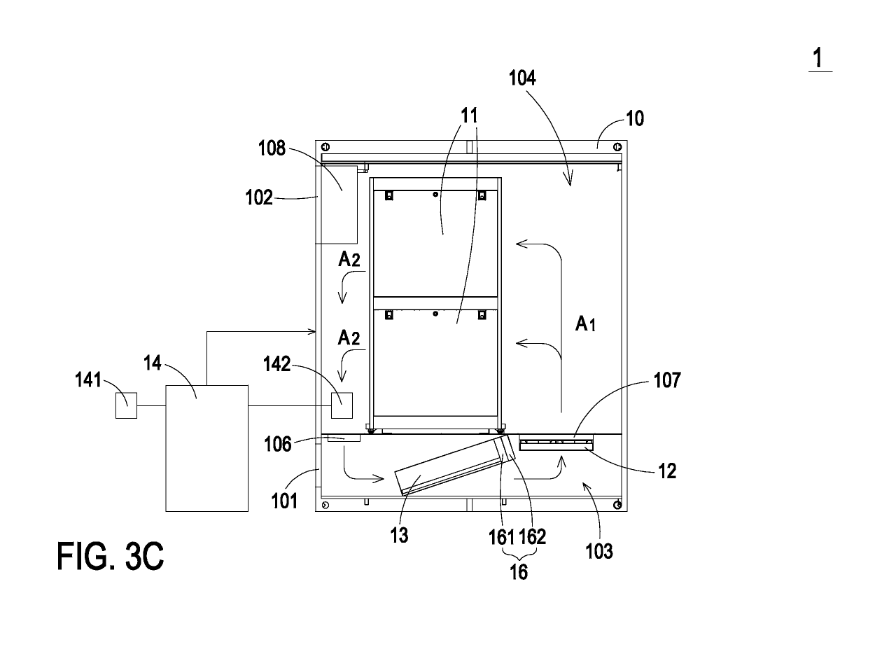

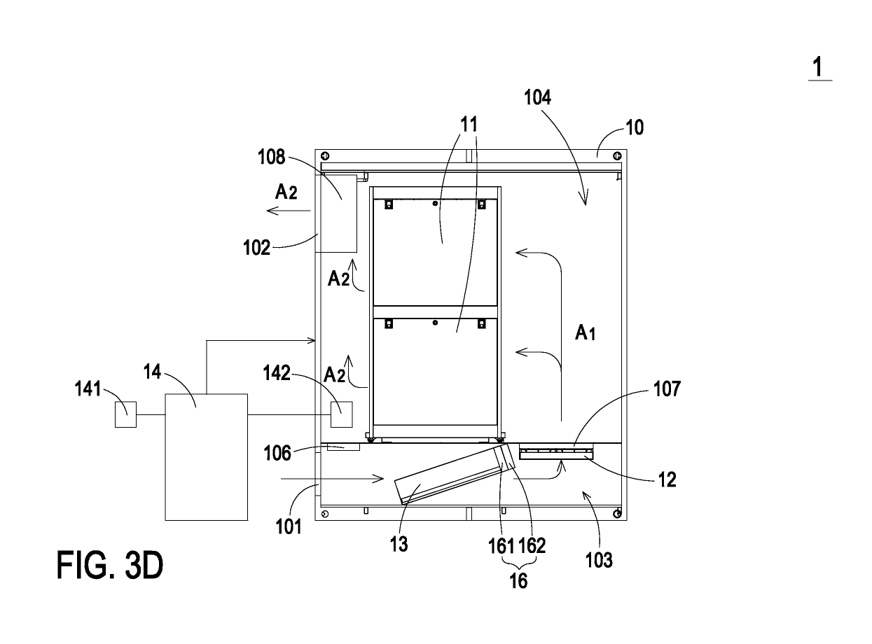

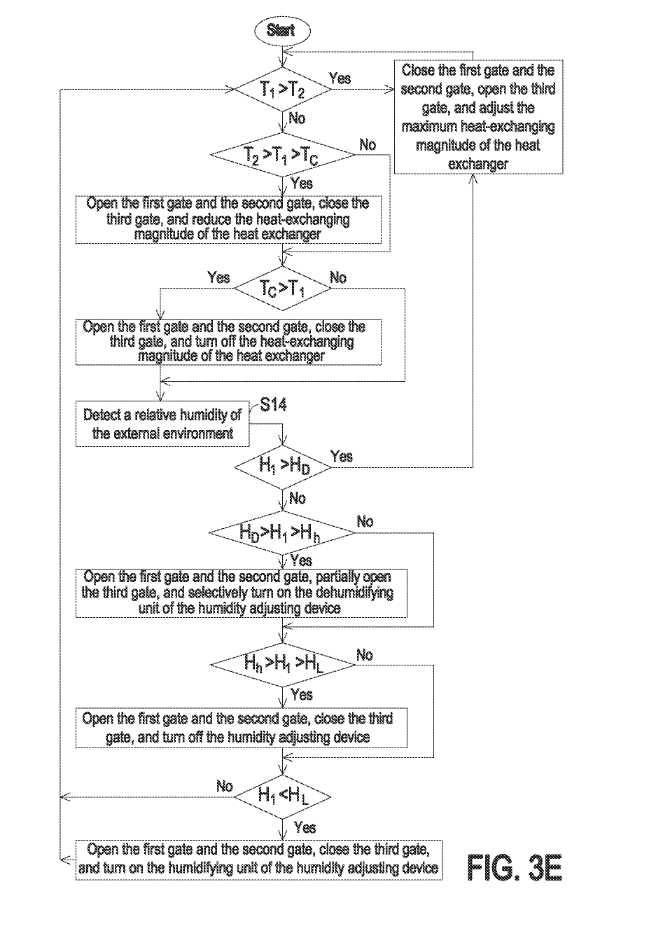

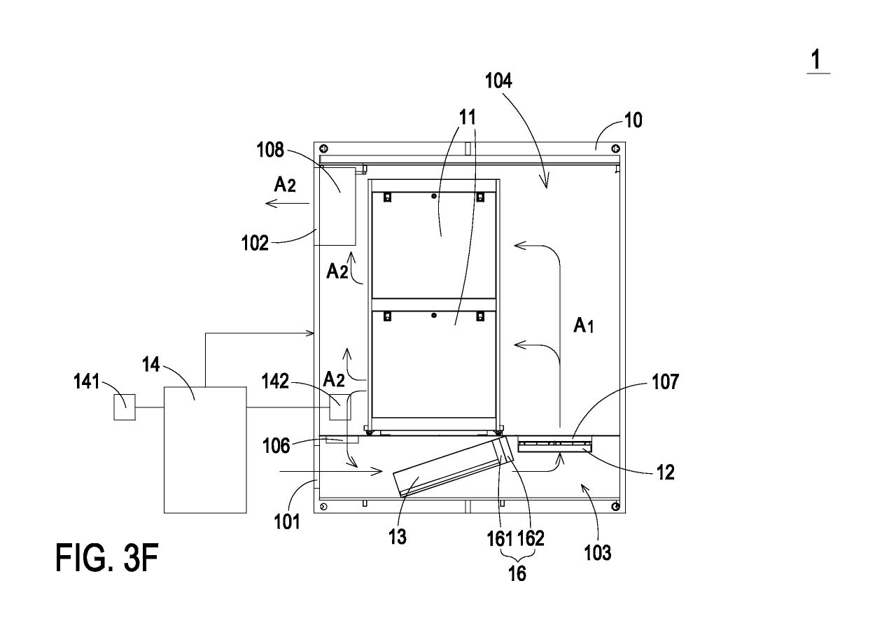

FIG. 3A is a flowchart illustrating an operating condition adjusting method according to an embodiment of the present invention. The operating condition adjusting method can be applied to the operating condition adjusting system 1 as shown in FIGS. 1 and 2. The operating condition adjusting method is implemented by the controlling unit 14. First of all, a first temperature T1 of the external environment outside the shipping container 10 is detected by the first sensor 141 (Step S11). Then, the first temperature T1 is compared with a second temperature T2 and the allowable temperature Tc of the shipping container 10 (Step S12). The allowable temperature Tc is the highest allowable temperature of the first airflow A1, which is used for cooling the computer cabinets 11. For example, the allowable temperature Tc is 10° C. Depending on the dimension of the shipping container 10 and the number of the computer cabinets 11, the allowable temperature Tc is varied. In this embodiment, the second temperature T2 is set to be equal to the temperature Ta of the second airflow A2. In other words, after S11 and before S12, the operating condition adjusting method further comprises a step of detecting the temperature Ta of the second airflow A2 and setting the second temperature T2 to be equal to the temperature Ta of the second airflow A2 (Step S11). It is noted that the second temperature T2 is higher than the allowable temperature Tc. According to the result of comparing the first temperature T1 with the second temperature T2 (and the allowable temperature Tc), the controlling unit 14 controls the open/close statuses of the first gate 101 and the second gate 102 in order to adjust the heat-exchanging magnitude of the heat exchanger 13 (Step S13).

FIG. 3B is a detailed flowchart illustrating Step S12 and S13 of the operating condition adjusting method as illustrated in FIG. 3A. If the controlling unit 14 judges that the first temperature T1 is higher than the second temperature T2, it is meant that the first temperature T1 of the external environment is higher than the temperature Ta of the second airflow A2. Meanwhile, under control of the controlling unit 14, the first gate 101 and the second gate 102 are closed and the third gate 106 is opened. As such, the airflow circulated within the shipping container 10 (i.e. close circulation). The second airflow A2 flows from the second compartment 104 to the first compartment 103 through the third gate 106 (see FIG. 3C). For reducing the temperature Ta of the second airflow A2, a maximum heat-exchanging magnitude of the heat exchanger 13 will be adjusted by the controlling unit 14. For example, the water chiller and the chilled water pump are fully opened. The second airflow A2 is introduced to the heat exchanger 13, and then a cooled first airflow A1 is obtained. By means of the heat exchanger 13, the first airflow A1 is reduced to be equal to or lower than the allowable temperature Tc. Through the airflow-guiding device 12 and the fourth gate 107, the first airflow A1 is guided to the computer cabinets 11. Since the second gate 102 is closed, the fan 108 could be turned off under control of the controlling unit 14 in order to reduce power consumption.

If the first temperature T1 is lower than the second temperature T2 and higher than the allowable temperature Tc, under control of the controlling unit 14, the first gate 101 and the second gate 102 are opened but the third gate 106 is closed. Since the second gate 102 is opened, the fan 108 is turned on. The second airflow A2 is exhausted out of the shipping container 10 through the second gate 102 (see FIG. 3D). The airflow outside the shipping container 10 is guided by the airflow-guiding device 12 and introduced into the first compartment 103 through the first gate 101. Since the first temperature T1 of the external environment is still higher than allowable temperature Tc, the heat-exchanging magnitude of the heat exchanger 13 is reduced under control of the controlling unit 14. The operating mode of the heat exchanger 13 could be selected according to a difference between the first temperature T1 and the allowable temperature Tc. For example, when the water chiller and the chilled water pump of the heat exchanger 13 is automatically switched to a medium or low flow mode, the external airflow is introduced to the heat exchanger 13, and then a cooled first airflow A1 is obtained. By means of the heat exchanger 13, the first airflow A1 is reduced to be equal to or lower than the allowable temperature Tc. Through the airflow-guiding device 12 and the fourth gate 107, the first airflow A1 is guided to the computer cabinets 11. The second airflow A2 is guided by the fan 108 to be exhausted out of the shipping container 10 through the second gate 102. As a consequence, an open circulation of the shipping container 10 is achieved to adjust the operating condition.

If the first temperature T1 is lower than the allowable temperature Tc, under control of the controlling unit 14, the first gate 101, the second gate 102 are opened, the fan 108 is turned on, but the third gate 106 is closed. As a consequence, an open circulation of the shipping container 10 is achieved. The circulation path of the airflow is similar to that shown in FIG. 3D, and is not redundantly described herein. Since the first temperature T1 of the external environment is lower than the allowable temperature Tc, the temperature of the external air induced into the first compartment 103 does not need to be reduced. Under control of the controlling unit 14, the heat exchanger 13 is turned off. In other words, the external air induced into the first compartment 103 through the first gate 101 is directly used as the first airflow A1. Through the airflow-guiding device 12 and the fourth gate 107, the first airflow A1 is guided to the computer cabinets 11. Similarly, the second airflow A2 is exhausted out of the shipping container 10 through the second gate 102.

In the above embodiment, the first gate 101, the second gate 102, the third gate 106, the fan 108 and the heat exchanger 13 are controlled by the controlling unit according to the result of comparing the first temperature T1 with the second temperature T2.

In some embodiments, the first gate 101, the second gate 102, the third gate 106, the fan 108 and the heat exchanger 13 are controlled by the controlling unit 14 according to result of comparing the humidity of the external environment with associated humidity. Please refer to FIG. 3A again. After Step S13, a relative humidity H1 of the external environment outside the shipping container 10 is detected by the first sensor 141 (Step S14). Then, the relative humidity H1 of the external environment is compared with a predetermined humidity Hd, a first allowable humidity Hh and a second allowable humidity HL (Step S15). The first allowable humidity Hh and the second allowable humidity HL are respectively the upper limit and the lower limit of the acceptable humidity range of the shipping container 10. In other words, the humidity value ranged between the first allowable humidity Hh and the second allowable humidity HL is acceptable. For example, in a case that the shipping container 10 is suitably operated at a humidity of 55%˜40%, it is meant that the first allowable humidity Hh is 55% and the second allowable humidity HL is 40%. The second allowable humidity HL is lower than the first allowable humidity Hh. The first allowable humidity Hh is lower than the predetermined humidity Hd (e.g. 95%). After Step S15, the open/close statuses of the first gate 101, the second gate 102 and the third gate 106 are controlled by the controlling unit 14 according to the result of comparing the relative humidity H1 of the external environment with the predetermined humidity Hd, the first allowable humidity Hh and the second allowable humidity HL, and the humidity adjusting device 16 is controlled by the controlling unit 14 (Step S16).

FIG. 3E is a detailed flowchart illustrating Step S12˜S16 of the operating condition adjusting method as illustrated in FIG. 3A. According to the result of comparing the first temperature T1 with the second temperature T2 and the allowable temperature Tc, the open/close statuses of the first gate 101, the second gate 102 and the third gate 106 and the on/off statuses of the fan 108 are controlled by the controlling unit 14 in order to adjust the heat-exchanging magnitude of the heat exchanger 13. The principle of adjusting the heat-exchanging magnitude of the heat exchanger 13 is similar to that illustrated in FIG. 3B, and is not redundantly described herein.

If the relative humidity H1 of the external environment detected by the first sensor 141 is higher than the predetermined humidity Hd (e.g. 95%), under control of the controlling unit 14, the first gate 101 and the second gate 102 are closed but the third gate is opened. In addition, a maximum heat-exchanging magnitude of the heat exchanger 13 is adjusted by the controlling unit 14. In such situation, a close circulation of the shipping container 10 is achieved (see also FIG. 3C) in order to prevent the external air from corroding the components of the computer cabinets 11. If the relative humidity H1 of the external environment detected by the first sensor 141 is lower than the predetermined humidity Hd and higher than the first allowable humidity Hh, under control of the controlling unit 14, the first gate 101 and the second gate 102 are opened and thus an open circulation of the shipping container 10 is achieved. For reducing the humidity of the external air, the third gate 106 is opened under control of the controlling unit 14. The second airflow A2, which is relatively hotter and drier, is partially exhausted out of the shipping container 10 through the second gate 102 and partially introduced into the first compartment 103 through the third gate 106. The second airflow A2 introduced into the first compartment 103 through the third gate 106 and the external airflow introduced into the first compartment 103 through the first gate 101 are mixed to adjust the humidity (see FIG. 3F). If the humidity of the mixed airflow is still higher than the first allowable humidity Hh, the dehumidifying unit 161 of the humidity adjusting device 16 is selectively controlled by the controlling unit 14 to perform a dehumidifying operation. If the relative humidity H1 of the external environment detected by the first sensor 141 is lower than the first allowable humidity Hh and higher than the second allowable humidity HL, it is means the relative humidity H1 of the external environment is within the acceptable range of the shipping container 10. Under control of the controlling unit 14, the first gate 101 and the second gate 102 are opened but the third gate 106 is closed, and thus an open circulation of the shipping container 10 is achieved. Meanwhile, the humidity adjusting device 16 is turned off. If the relative humidity H1 of the external environment detected by the first sensor 141 is lower than the second allowable humidity HL, under control of the controlling unit 14, the first gate 101 and the second gate 102 are opened but the third gate 106 is closed, and thus an open circulation of the shipping container 10 is achieved. In addition, the humidifying unit 162 of the humidity adjusting device 16 is opened under control of the controlling unit 14. As such, the external airflow introduced into the first compartment 103 through the first gate 102 is wetted by the humidifying unit 162 in order to prevent from the components of the computer cabinets 11 from generating static electricity. Moreover, once the second gate 102 is opened, the fan 108 may be turned off under control of the controlling unit 14, so that the circulating efficacy is enhanced. During the open circulation of the shipping container 10 is performed, the heat exchanger 13 and the humidity adjusting device 16 are independently controlled by the controlling unit 14.

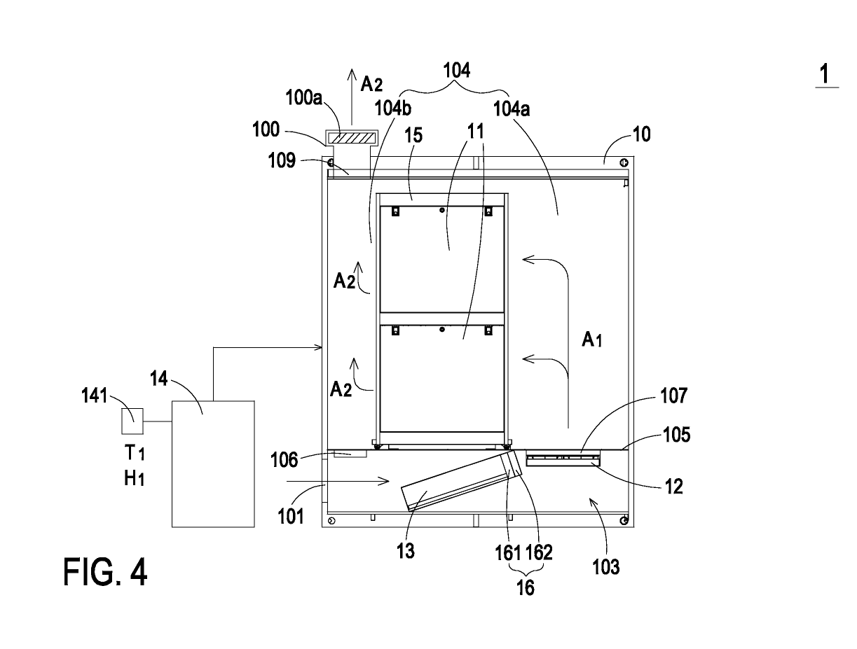

FIG. 4 is a schematic cross-sectional view illustrating an operating condition adjusting system according to another embodiment of the present invention. The configurations of the shipping container 10, the first gate 101, the first compartment 103, the second compartment 104, the air-inlet zone 104a, the air-outlet zone 104b, the partitioning structure 105, the third gate 106 and the fourth gate 107 included in the operating condition adjusting system of this embodiment are similar to those shown in FIG. 1C, and are not redundantly described herein. The configurations of the computer cabinets 11, the airflow-guiding device 12, the heat exchanger 13 and the humidity adjusting device 16 are also similar to those shown in FIG. 1C. In this embodiment, the second gate 109 is formed at the upper side of the shipping container 10 and in communication with the air-outlet zone 104b of the second compartment 104. In addition, a chimney-like exhaust pipe 100 is extended upwardly from the second gate 109. Moreover, plural turbine blades 100a are disposed on the outlet of the exhaust pipe 100 for increasing the speed of exhausting the second airflow A2 through the second gate 109 and the exhaust pipe 100. When the second gate 109 is opened, a naturally-convectional ventilation door is created at the position of the second gate 109. The shipping container 10 of FIG. 4 is illustrated by referring to an open circulation mode. In a case that a close circulation of the shipping container 10 is rendered, the circulation path is substantially identical to that of FIG. 3C.

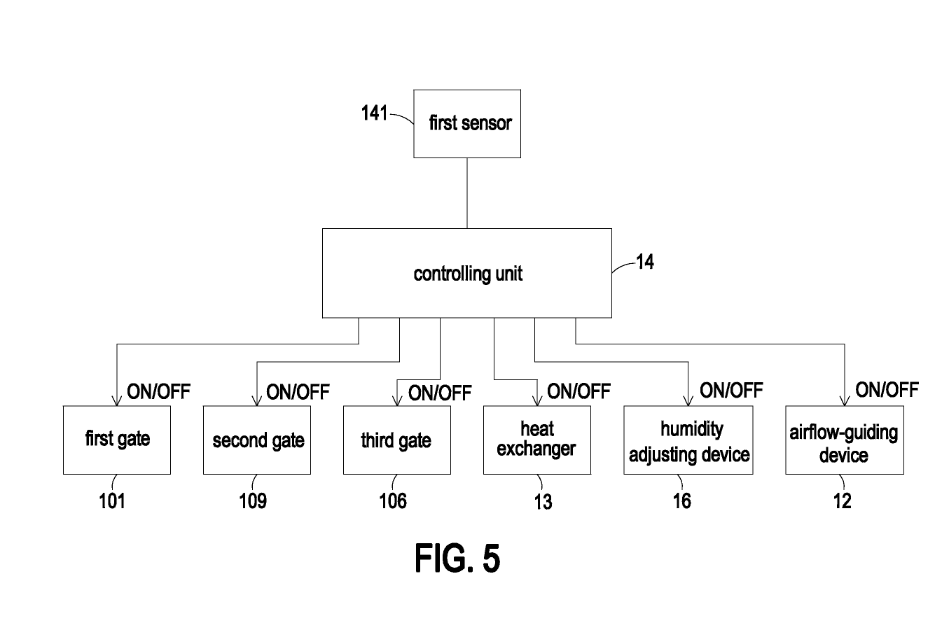

FIG. 5 is a schematic functional block diagram illustrating a controlling mechanism of the controlling unit of the operating condition adjusting system of FIG. 4. As shown in FIGS. 4 and 5, the operating condition adjusting system only comprises a first sensor 141. The first sensor 141 is electrically connected with the controlling unit 14, and disposed outside the shipping container 10. The first sensor 141 is used for detecting the first temperature T1 and a first humidity H1 of the external environment. In this embodiment, the second temperature T2 is not equal to the temperature Ta of the second airflow A2. The second temperature T2 is a predetermined temperature Td (e.g. 40° C.), which can be set according to the practical requirements. The predetermined temperature Td may be higher than the allowable temperature Tc. By comparing the first temperature T1 with the second temperature T2 (i.e. the predetermined temperature Td) and the allowable temperature Tc, the no/off statuses of the first gate 101, the second gate 102, the fan 108, the third gate 106, the heat exchanger 13 and the heat-exchanging magnitude of the humidity adjusting device 16 are controlled by the controlling unit 14. The operating condition adjusting method includes the steps S11, S12, S13, S14, S15, S16 shown in FIG. 3A and similar to the flowcharts shown in FIGS. 3B and 3E.

In the above embodiments, the first temperature T1 of the external environment is firstly detected by the first detector 141. By comparing the first temperature T1 with the second temperature T2 (e.g. the temperature Ta of the second airflow A2 or the predetermined temperature Td) and/or the allowable temperature Tc, the controlling unit 14 will control the circulation mode of the shipping container 10. In a case that the first temperature T1 of the external environment is higher than the second temperature T2 or the relative humidity H1 is higher than the predetermined humidity Hd, a close circulation of the shipping container 10 is rendered. Whereas, in a case that the first temperature T1 of the external environment is lowered than the second temperature T2 or the allowable temperature Tc, under control of the controlling unit 14, the first gate 101 and the second gate 102 are opened but the third gate 106 is closed and the heat-exchanging magnitude of the heat exchanger 13 is adjusted. As such, the cool external airflow is introduced into the shipping container 10 in order to reduce loading and power consumption of the heat exchanger 13. For preventing the too wet (or too dry) external airflow from adversely influencing the computer cabinets 11, the relative humidity H1 of the external environment is also taken into consideration. According to the result of comparing the relative humidity H1 with the predetermined humidity Hd and the acceptable humidity range of the shipping container 10, the controlling unit 14 further controls the third gate 106 and the humidity adjusting device 16. As a consequence, the open circulation of the shipping container 10 is rendered, and the humidity within the shipping container 10 is dynamically controlled.

Since the airflow-guiding device 12 is a variable-frequency fan and the heat exchanger 13 includes a variable-frequency water chiller, the controlling unit 14 can dynamically adjust the rotating speed of the airflow-guiding device 12 and the heat-exchanging magnitude of the heat exchanger 13 according to the result of comparing the first temperature T1 with the second temperature T2 and the allowable temperature Tc. In other words, the operating conditions of the portable data center could be stably adjusted and the power consumption efficacy will be achieved. Optionally, a filter (not shown) is disposed at the first gate 10 for filtering the external airflow that is introduced into the shipping container 10. In the above embodiments, the controlling unit 14 is disposed outside the shipping container 10. Nevertheless, the controlling unit 14 may be disposed within the shipping container 10. For example, the controlling unit 14 and the computer cabinets 11 are collectively disposed within the second compartment 104 of the shipping container 10.

In the above embodiments, the first gate and the second gate controllable by the controlling unit are installed in the sidewalls of the shipping container; and the third gate, the heat exchanger and the airflow-guiding device controllable by the controlling unit are disposed within the shipping container. In a case that the first temperature of the external environment is higher than the second temperature, under control of the controlling unit, the first gate and the second gate are closed but the third gate is opened to perform a close circulation, and the maximum heat-exchanging magnitude is adjusted. In a case that the first temperature of the external environment is lower than the second temperature (e.g. during the night in winter or spring), under control of the controlling unit, the first gate and the second gate are opened but the third gate is closed to perform an open circulation, and the heat-exchanging magnitude is reduced because the cool external airflow is introduced into the shipping container. In this situation, the power consumption of the heat exchanger is reduced. In a case that the first temperature of the external environment is lower than the allowable temperature of the shipping container, the heat exchanger may be turned off.

By using the operating condition adjusting system of the present invention, about one fourth of power consumption magnitude of the heat exchanger is saved. As a consequence, the operating cost is reduced and the power-saving purpose is achieved. For preventing the too wet (or too dry) external airflow from adversely influencing the computer cabinets when the first gate and the second gate are opened, the relative humidity of the external environment is also taken into consideration. According to the result of comparing the relative humidity with the predetermined humidity and the acceptable humidity range of the shipping container, the controlling unit further controls the third gate and the humidity adjusting device. As a consequence, the operating conditions of the shipping container will be optimized, and the power-saving purpose is achieved.

Since the airflow-guiding device is a variable-frequency fan and the heat exchanger includes a variable-frequency water chiller, the power consumption efficacy is enhanced. In addition, the close circulation mode or the open circulation mode of the shipping container is automatically controlled by the controlling unit, the operating cost is reduced.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. An operating condition adjusting system of a data center, said operating condition adjusting system comprising:
a shipping container comprising at least one first gate and at least one second gate;
plural computer cabinets accommodated within said shipping container, wherein a first airflow is introduced into said computer cabinets to remove a portion of heat of said computer cabinets, and a second airflow is exhausted from said computer cabinets;
an airflow-guiding device disposed within said shipping container for guiding said first airflow to flow toward the computer cabinets;
a controlling unit for controlling said first gate and said second gate of said shipping container; and
a first sensor electrically connected with said controlling unit for detecting a first temperature of an external environment,
wherein by comparing said first temperature with a second temperature, said first gate and said second gate are opened or closed under control of said controlling unit.

2. The operating condition adjusting system according to claim 1 further comprising:
a second sensor electrically connected with said controlling unit, disposed within said shipping container and arranged in a path of said second airflow, wherein said second temperature is equal to a temperature of said second airflow detected by said second sensor.

3. The operating condition adjusting system according to claim 1 wherein said second temperature is a predetermined temperature.

4. The operating condition adjusting system according to claim 1 further comprising a heat exchanger, which is disposed within said shipping container for adjusting a temperature of said first airflow.

5. The operating condition adjusting system according to claim 4 wherein said shipping container further comprises a first compartment and a second compartment, said heat exchanger is disposed within said first compartment, and said computer cabinets are disposed within said second compartment, wherein said first compartment is in communication with an external environment once said first gate is opened, and said second compartment is in communication with said external environment once said second gate is opened.

6. The operating condition adjusting system according to claim 5 wherein said first compartment and said second compartment are separated from each other by a partitioning structure, and said shipping container further comprises a third gate and a fourth gate running through said partitioning structure, wherein said third gate is controllable by said controlling unit.

7. The operating condition adjusting system according to claim 6 wherein said second compartment of said shipping container comprises an air-inlet zone and an air-outlet zone, which are separated from each other by said computer cabinets, wherein said first airflow is introduced into said computer cabinets through said air-inlet zone to remove a portion of heat of said computer cabinets, and said second airflow is exhausted from said computer cabinets to said air-outlet zone, wherein said air-outlet zone of said second compartment is in communication with said external environment once said second gate is opened.

8. The operating condition adjusting system according to claim 7 wherein said third gate of said shipping container is arranged between said first compartment and said air-outlet zone of said second compartment, wherein said first compartment and said air-outlet zone of said second compartment are in communication with each other once said third gate is opened.

9. The operating condition adjusting system according to claim 7 wherein said fourth gate of said shipping container is arranged between said first compartment and said air-inlet zone of said second compartment, wherein said first compartment and said air-inlet zone of said second compartment are in communication with each other once said fourth gate is opened.

10. The operating condition adjusting system according to claim 5 wherein a relative humidity of said external environment is further detected by said first sensor, and said operating condition adjusting system further comprises a humidity adjusting device, which is disposed within said first compartment and controllable by said controlling unit, wherein said humidity adjusting device comprises a dehumidifying unit and a humidifying unit.

11. The operating condition adjusting system according to claim 10 wherein by comparing said relative humidity with a predetermined humidity and a first allowable humidity and a second allowable humidity of said shipping container, under control of said controlling unit, open/close statuses of said first gate, said second gate and said third gate are controlled and said humidity adjusting device is adjusted.

12. The operating condition adjusting system according to claim 1 further comprising:
a fan installed in said second gate and controllable by said controlling unit; and
an exhaust pipe, wherein plural blades are disposed on said exhaust pipe.

13. An operating condition adjusting method for use in an operating condition adjusting system of a data center, said operating condition adjusting system comprising a shipping container, plural computer cabinets, an airflow-guiding device, a heat exchanger and a controlling unit, said shipping container comprising a first gate and a second gate, said shipping container being in communication with an external environment when said first gate and said second gate are opened, said computer cabinets, said heat exchanger and said airflow-guiding device are accommodated with said shipping container, wherein a first airflow is guided by said airflow-guiding device to said computer cabinets to remove a portion of heat of said computer cabinets, and a second airflow is exhausted from said computer cabinets, wherein said operating condition adjusting method is controlled by said controlling unit, and comprises steps of:
(a) detecting a first temperature of said external environment;
(b) comparing said first temperature with a second temperature and an allowable temperature of said shipping container; and
(c) controlling on/off statuses of said first gate and said second gate and adjusting a heat-exchanging magnitude of said heat exchanger according to a result of comparing said first temperature with said second temperature and said allowable temperature.

14. The operating condition adjusting method according to claim 13 wherein said step (a) further comprises a sub-step (a1) of detecting a temperature of said second airflow within said shipping container, thereby obtaining said second temperature.

15. The operating condition adjusting method according to claim 13 wherein said second temperature is a predetermined temperature.

16. The operating condition adjusting method according to claim 13 wherein said shipping container further comprises a third gate, which is controllable by said controlling unit.

17. The operating condition adjusting method according to claim 16 wherein if said comparing result of said step (c) indicates that said first temperature is higher than said second temperature, said step (c) further comprises a sub-step (c1) of closing said first gate and said second gate but opening said first gate to perform a close circulation, and adjusting a maximum heat-exchanging magnitude of said heat exchanger, so that said second airflow is introduced to said heat exchanger through said third gate, and said first airflow is obtained from said heat exchanger and guided to said computer cabinets by said airflow-guiding device.

18. The operating condition adjusting method according to claim 16 wherein if said comparing result of said step (c) indicates that said first temperature is lower than said second temperature and higher than said allowable temperature, said step (c) further comprises a sub-step (c1) of opening said first gate and said second gate but closing said third gate to perform an open circulation, and reducing said heat-exchanging magnitude of said heat exchanger, so that an external airflow is introduced into said shipping container through said first gate and contacted with said heat exchanger, said first airflow is obtained from said heat exchanger and guided to said computer cabinets by said airflow-guiding device, and said second airflow is exhausted to said external environment through said second gate.

19. The operating condition adjusting method according to claim 16 wherein said second temperature is higher than said allowable temperature, wherein if said comparing result of said step (c) indicates that said first temperature is lower than said allowable temperature, said step (c) further comprises a sub-step (c1) of opening said first gate and said second gate but closing said third opening to perform an open circulation, and disabling said heat exchanger, so that an external airflow is introduced into said shipping container through said first gate to be served as said first airflow, said first airflow is guided to said computer cabinets by said airflow-guiding device, and said second airflow is exhausted to said external environment through said second gate.

20. The operating condition adjusting method according to claim 16 wherein said operating condition adjusting further comprises a humidity adjusting device, which is controllable by said controlling unit, and includes a dehumidifying unit and a humidifying unit, wherein said operating condition adjusting method further comprises steps of:
(d) detecting a relative humidity of said external environment;
(e) comparing said relative humidity with a predetermined humidity and a first allowable humidity and a second allowable humidity of said shipping container, wherein said predetermined humidity is higher than said first allowable humidity, and said first allowable humidity is higher than said second allowable humidity; and
(f) controlling on/off statuses of said first gate, said second gate and said third gate and adjusting a heat-exchanging magnitude of said heat exchanger according to a result of comparing said relative humidity with said predetermined humidity, said first allowable humidity and said second allowable humidity.

21. The operating condition adjusting method according to claim 20 wherein if said comparing result of said step (f) indicates that said relative humidity is higher than said predetermined humidity, said step (f) further comprises a sub-step (f1) of closing said first gate and said second gate but opening said first gate to perform a close circulation, and adjusting a maximum heat-exchanging magnitude of said heat exchanger.

22. The operating condition adjusting method according to claim 20 wherein if said comparing result of said step (f) indicates that said relative humidity is lower than said predetermined humidity and higher than first allowable humidity, said step (f) further comprises sub-steps of:
partially opening said third gate and opening said first gate and said second gate to perform an open circulation, so that an external airflow introduced into said shipping container through said first gate and said second airflow flowing through said third gate are mixed to adjust humidity; and
turning on said dehumidifying unit of said humidity adjusting device.

23. The operating condition adjusting method according to claim 20 wherein if said comparing result of said step (f) indicates that said relative humidity is lower than said first allowable humidity and higher than said second allowable humidity, said step (f) further comprises a sub-step (f1) of opening said first gate and said second gate but closing said third gate to perform an open circulation, and turning off said humidity adjusting device, wherein if said comparing result of said step (f) indicates that said relative humidity is lower than said second allowable humidity, said step (f) further comprises a sub-step (f1) of opening said first gate and said second gate but closing said third gate to perform an open circulation, and turning on said humidifying unit of said humidity adjusting device.
